(19) United States
(12) Patent Application Publication
(10) Pub. No.: US 2010/0025725 A1
(43) Pub. Date: Feb. 4, 2010

(54) SEMICONDUCTOR DEVICE AND METHOD FOR PRODUCTION THEREOF

(76) Inventor: Hiroaki Tanaka, Aichi-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/514,637

(22) PCT Filed: Nov. 13, 2007
(86) PCT No.: PCT/IB07/03477

§ 371 Date: May 13, 2009

(30) Foreign Application Priority Data
Nov. 14, 2006 (JP) 2006-307790

(51) Int. Cl. H01L 29/739; H01L 21/331

(52) U.S. Cl. 257/139; 438/138; 257/E29.198; 257/E21.384

(57) ABSTRACT

A semiconductor device has a drift region (20) (third semiconductor region) of an n-type (first conductivity type); a body region (50) (second semiconductor region) of a p-type (second conductivity type) provided on the drift region (20); an emitter region (60) (first semiconductor region) of the n-type formed in the top surface of the body region (50) and separated from the drift region (20) by the body region (50); a trench (14) extending from the top surface of the emitter region (60) through the body region (50) into the drift region (20); a trench gate electrode (13) filled in the trench (14); and a semiconductor region (70) (fourth semiconductor region) of the p-type formed in contact with side faces of the trench protruding into the drift region (20). Therefore, the semiconductor device can suppress a surge voltage at turn-off, and can be produced easily.

### BACKGROUND OF THE INVENTION

1. Field of the Invention

The present invention relates to an art for suppressing a surge voltage at turn-off of a semiconductor device.

2. Description of the Related Art

At turn-off of a semiconductor device, a voltage surge is sometimes generated that may adversely affect the semiconductor device. JP-A-2004-193212 describes an insulated gate bipolar transistor (IGBT) that suppresses voltage surges. The IGBT has a p-type collector region 400 and a buffer region 302 as shown in FIG. 12. In the IGBT 100, an n⁺-type buffer region 301 provided in the middle of an n⁻-type drift region divides the n⁻-type drift region into a first drift region 201 on the top surface side and a second drift region 202 on the bottom surface side. In this configuration, holes emitted from the collector region 400 are accumulated in the second drift region 202. When the IGBT 100 is turned ON, channel regions are formed in regions facing the gate electrodes 114 via gate insulator 112 in the p⁻-type body region 500. Then, electrons emitted from n⁺-type emitter regions 600 move through the channel regions to the first drift region 201, the buffer region 301, the second drift region 202, and the buffer region 302. Thus, holes are injected from the collector region 400 into the buffer region 302, the second drift region 202, the buffer region 301, and the first drift region 201. The electrons and the holes injected into the first drift region 201, the buffer region 301, the second drift region 202, and the buffer region 302 modulate conductivity, and a current flows between the emitter regions 600 and the collector region 400. When the IGBT 100 is shifted from the ON state to the OFF state (at turn-off), a depletion layer spreads from the p-n junction between the p⁻-type body region 500 and the n⁻-type first drift region 201. In conventional IGBTs, the depletion layer suddenly spreads to the buffer region 302 at turn-off and a surge voltage with a high peak value is generated. Because the IGBT 100 in the related art has the additional buffer region 301, a depletion layer spreads downward from the p-n junction but the spread is blocked by the buffer region 301. As a result, many holes may remain in the second drift region 202 until the turn-off operation is completed. When the IGBT 100 is used, a depletion layer does not suddenly spread to the buffer region 302 at turn-off, and the surge voltage may be suppressed.

In the IGBT 100 described in the related art document, an n⁺-type buffer region 301 is provided between an n⁻-type first drift region 201 and an n⁻-type second drift region 202 to suppress a surge voltage at turn-off. Here, methods for forming the regions will be discussed. In one method, an n⁻-type semiconductor layer is prepared. Then, the n⁻-type semiconductor layer is implanted with an n-type impurity at a specific position from the bottom of the n⁻-type semiconductor layer to form a buffer region 301. In the IGBT 100 described in the related art document, the buffer region 301 is formed at a depth of approximately 10 μm from the bottom surface. To implant an impurity in the position from the bottom surface, high energy is required, and therefore the production costs increase. Another method may be applied such that an n⁺-type buffer region 301 is formed by epitaxial growth on an n⁻-type second drift region 202. Then, an n⁻-type first drift region 201 is formed on the n⁺-type buffer region 301 by epitaxial growth. However, it takes long time to form these regions by sequential epitaxial growth, and the production costs of the semiconductor device increase.

### SUMMARY OF THE INVENTION

The present invention provides a semiconductor device that can be produced easily and that is capable of suppressing a voltage surge. Although an insulated gate bipolar transistor (IGBT) is described as an example in the above, the art of the present invention is not limited to the IGBT.

A semiconductor device according to a first aspect of the present invention includes: a third semiconductor region of a first conductivity type; a second semiconductor region of a second conductivity type provided on the third semiconductor region; a first semiconductor region of the first conductivity type formed in a top surface of the second semiconductor region and spaced from the third semiconductor region by the second semiconductor region; a trench extending from a top surface of the first semiconductor region through the second semiconductor region into the third semiconductor region and having a pair of side faces opposed to each other and separated by a space; an insulating layer covering wall surfaces of the trench; a trench gate electrode surrounded by the insulating layer and disposed in the trench; and a fourth semiconductor region of the second conductivity type formed in contact with the side faces of the trench protruding into the third semiconductor region.

The first aspect of the present invention is applicable to semiconductor devices which have a trench gate electrode and in which the carrier moves in the vertical (direction such as IGBT and MOSFET. In the case of an IGBT the third semiconductor region may be regarded as a drift region, the second semiconductor region may be regarded as a body region, and the first semiconductor region may be regarded as an emitter region. In the case of a MOSFET, the third semiconductor region may be regarded as a drift region, the second semiconductor region may be regarded as a body region, and the first semiconductor region may be regarded as a source region.

In general, a parasitic inductance exists in the line on the output side of a semiconductor device. When the parasitic inductance is defined as La and the current, which flows between the collector and the emitter of the semiconductor device, is defined as Ice, a surge voltage of La×(dIce/dt) is generated between the collector and the emitter at turn-off. Thus, the peak value of the surge voltage decreases when the rate of decrease (dIce/dt) of the current Ice at turn-off decreases. The rate of decrease (dIce/dt) decreases when the capacitance Cge between the gate and the emitter is increased and the capacitance Cgc between the gate and the collector is decreased.

Although a bipolar semiconductor device using a collector and an emitter in the above is described, the same holds true for a unipolar semiconductor device using a drain and a source. When the capacitance between the gate and the source is increased, the rate of decrease of the current between the drain and the source at turn-off decreases, thereby suppressing the surge voltage. In the following description, the capacitance Cge means the capacitance between the gate and the emitter in the case of a bipolar semiconductor device, and the capacitance between the gate and the source in the case of a unipolar semiconductor device. The capacitance Cgc means the capacitance between the gate and the collector in the case of a bipolar semiconductor device, and the capacitance between the gate and the drain in the case of a unipolar semiconductor device. The current Ice means the current between the collector and the emitter in the case of a bipolar semiconductor device, and the current between the drain and the source in the case of a unipolar semiconductor device.

The capacitance Cge varies depending on the sum of the length L1 of channel regions, which form while the semiconductor device is turned on, and the depth L3 of the emitter regions (see FIG. 13), and the value of the capacitance Cge will increase with increases in the value of the sum (L1+L3). The capacitance Cgc varies depending on the length L2 from the bottom surface of the body region to the bottoms of the trench gate electrodes, and the capacitance Cgc will increase with increases in the length L2. When the capacitance Cge is increased to suppress a surge voltage, it is desirable to increase the value of the sum of the length L1 of the channel regions and the depth L3 of the emitter regions (L1+L3). However, when the depth L3 of the emitter regions is increased, there is a possibility of a decrease in latch-up resistance. Therefore, the depth of the body region is often increased without changing the depth L3 of the emitter regions as shown in FIG. 14. The value of the sum (L1+L3) increases because the value of the length L1 is increased and the value of the length L2 is decreased. Then, the capacitance Cge increases and the capacitance Cgc decreases, and therefore the rate of decrease (dIce/dt) of the current Ice at turn-off decreases. The surge voltage at turn-off can be suppressed without causing a decreasing latch-up resistance.

However, if the depth of the body region is simply increased as shown in FIG. 14, the volume of the drift region (third semiconductor region) decreases and holes (schematically shown by plus signs in the drawing) emitted from the collector region cannot be sufficiently accumulated. When the amount of holes in the drift region decreases, an active conductivity modulation phenomenon does not occur and the on-voltage increases. When the depth of the body region is increased, the surge voltage at turn-off can be suppressed but the on-voltage increases.

The semiconductor device according to the first aspect of the present invention has a fourth semiconductor region. The fourth semiconductor region is formed in contact with the side face of the trench extending into the third semiconductor region and is a second conductivity type. The fourth semiconductor region of the second conductivity type contact the second semiconductor region of the second conductivity type and may be regarded as extensions of the second semiconductor region. When the fourth semiconductor regions are provided, the length L1 is increased and the length L2 is decreased. Therefore, the capacitance Cge may be increased and the capacitance Cgc may be decreased, and the rate of decrease (dIce/dt) of the current Ice at turn-off may be decreased. As a result, a surge voltage at turn-off is suppressed.

It is known that, when the semiconductor device is an IGBT, the on-voltage of the semiconductor device may be decreased as the number of holes that stay in the drift region increases. The fourth semiconductor region of the present invention is formed only in the region in contact with the side face of the trench and not formed in a wide region between paired trench gate electrodes. Therefore, the volume of the third semiconductor region (drift region) is not significantly decreased, and the region capable of accumulating holes is not significantly decreased. Thus, an increase in on-voltage is avoided. In addition, the fourth semiconductor region is formed at a shallow region in contact with the exposed surface of the semiconductor substrate, while the details are described later. Therefore, the fourth semiconductor region can be easily formed by implanting an impurity into the exposed surface of the semiconductor substrate with low energy.

Also, the depth of the fourth semiconductor region from the side face of the trench may increase from the side of the bottom of the trench to the second semiconductor region. That is, the fourth semiconductor region may have a generally triangular shaped cross-section. In this case, the fourth semiconductor region can be formed relatively easily by obliquely implanting the impurity into the trench.

Also, a fifth semiconductor region of the second conductivity type may be provided on a bottom surface side of the third semiconductor region. In this case, a semiconductor device which functions as an IGBT may be obtained.

Also, a sixth semiconductor region of the first conductivity type may be provided between the third semiconductor region and the fifth semiconductor region. In this case, a punch through type IGBT may be obtained.

A second aspect of the present invention relates to a method for producing a semiconductor device. The production method includes the steps of: forming a second semiconductor region of a second conductivity type on a third semiconductor region of a first conductivity type; forming a first semiconductor region of the first conductivity type in a part of a top surface of the second semiconductor region; forming a trench extending from a top surface of the first semiconductor region through the second semiconductor region into the third semiconductor region and having a pair of side faces opposed to each other and spaced by a width; implanting an impurity of the second conductivity type toward the side faces of the trench from the top surface side of the second semiconductor region to form an impurity implanted region of the second conductivity type in at least the side faces of the trench extending into the third semiconductor region; and heat treating the semiconductor device forming a thermal oxidation film on wall surfaces of the trench and, simultaneously, activating the impurity in the impurity implanted region to form a fourth semiconductor region of the second conductivity type.

According to the method for producing a semiconductor device according to the second aspect of the present invention, a thermal oxidation film is formed on the wall surfaces of the trench to form a gate insulator and, at the same time, the impurity implanted in the impurity implanting step is activated in the heat treatment step. Therefore, the heat treatment for forming the gate insulator and the heat treatment for activating the impurity do not have to be performed separately, and the number of production steps may be reduced. Also, in the impurity implanting step, the side faces of the trenches are implanted with the impurity from top surface side of the second semiconductor region. That is, an oblique implanting method is adopted. In this case, the shallow regions of the side faces of the trench are implanted with a large amount of an impurity and the deep regions of the side faces of the trench are implanted with a small amount of the impurity. When heat treatment is performed in this state, the fourth semiconductor region, the depth of which from the side face of the trench increases from the side of the bottom of the trench to the second semiconductor region, is formed.

With the semiconductor device according to the second aspect of the present invention, the surge voltage at turn-off may be suppressed and an increase in on-voltage (on-resistance) is avoided. In addition, the semiconductor device can be assembled easily.

### BRIEF DESCRIPTION OF THE DRAWINGS

The foregoing and further objects, features and advantages of the invention will become apparent from the following description of example embodiments with reference to the accompanying drawings, wherein like numerals are used to represent like elements and wherein:

FIG. 1 is a cross-sectional view of a semiconductor device 10.

FIG. 2 is a view illustrating the changes in voltage Vge across a gate and an emitter at turn-on and at turn-off.

FIG. 3 is a view illustrating the changes in current Ice between a collector and an emitter at turn-on and at turn-off.

FIG. 4 is a view illustrating the changes in voltage Vce across a collector and an emitter at turn-on and at turn-off.

FIG. 5 is a view illustrating the fact that the semiconductor device 10 is capable of suppressing the surge voltage at turn-off while preventing a rise in the on-voltage.

FIG. 6 illustrates the production process of the semiconductor device 10.

FIG. 7 illustrates the production process of the semiconductor device 10.

FIG. 8 illustrates the production process of the semiconductor device 10.

FIG. 9 illustrates the production process of the semiconductor device 10.

FIG. 10 illustrates the production process of the semiconductor device 10.

FIG. 11 illustrates the production process of the semiconductor device 10.

FIG. 12 shows the constitution of a semiconductor device of the related art.

FIG. 13 is a view illustrating the related art.

FIG. 14 is a view illustrating the related art.

### DETAILED DESCRIPTION OF THE INVENTION

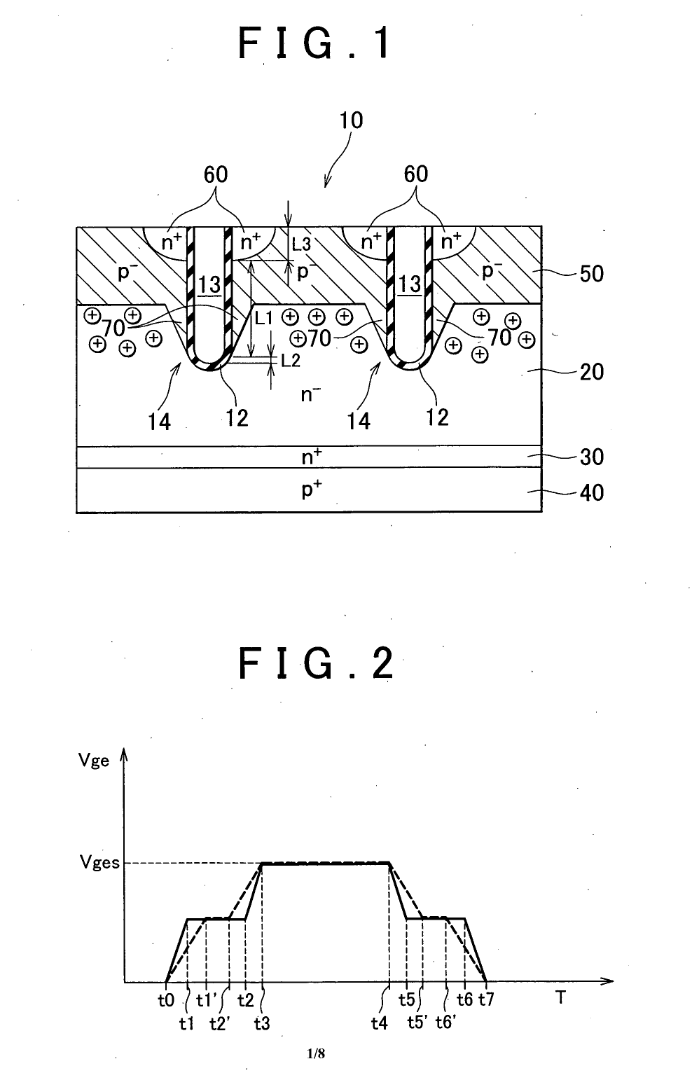

One embodiment of a semiconductor device according to the present invention and a method for the production thereof are described with reference to FIG. 1 to FIG. 11. The embodiment is obtained by applying the present invention to a punch through type IGBT having trench gate electrodes. FIG. 1 is a cross-sectional view of a semiconductor device 10 of this embodiment, and FIG. 2 to FIG. 5 are views illustrating the phenomenon in which a surge voltage generated at turn-off of a semiconductor device 10 is suppressed. FIG. 6 to FIG. 11 are views illustrating the production process of the semiconductor device 10.

First, the constitution of a semiconductor device 10 is described with reference to the cross-sectional view of FIG. 1. As shown in FIG. 1, the semiconductor device 10 has an n⁻-type drift region 20. An n⁺-type buffer region 30 is provided on the bottom surface (lower side in FIG. 1) of the drift region 20. A p⁺-type collector region 40 is provided on the bottom surface of the buffer region 30. A p⁻-type body region 50 is provided on the top surface (upper side in FIG. 1) of the drift region 20. In some parts of the top surface of the body region 50, n⁺-type emitter regions 60, 60 are formed. Trenches 14 are formed between paired emitter regions 60, 60 and adjacent to the emitter regions 60, 60. The trenches 14 extend from the top surface of the semiconductor device 10 through the body region 50 into the drift region 20. The trenches 14 are elongated in the vertical direction of the drawing. Each trench 14 has a pair of side faces opposed to each other and spaced by the trench width. The wall surfaces of each trench 14 are covered with a gate insulator 12. The spaces in the trenches 14 are filled with polysilicon to form trench gate electrodes 13. The trench gate electrodes 13 are surrounded by the gate insulators 12 and disposed in the trenches 14.

In the semiconductor device 10 of this embodiment, p⁻-type semiconductor regions 70 are formed in contact with the side faces of the trenches 14 extending into the drift region 20. The n⁺-type emitter regions 60, 60 may be regarded as first semiconductor regions, the p⁻-type body region 50 may be regarded as a second semiconductor region, the n⁻-type drift region 20 may be regarded as a third semiconductor region, and the p⁻-type semiconductor regions 70 may be regarded as fourth semiconductor regions. Each p⁻-type semiconductor region 70 has a triangle with a base in contact with a part of the bottom surface of the body region 50 as shown in the cross-sectional view of FIG. 1. The p⁻-type semiconductor regions 70 are integrated with the p⁻-type body region 50. The depth of the p⁻-type semiconductor regions 70 from the side faces of the trenches 14 increases from the side of the bottoms of the trenches 14 to the body region 50.

Because the semiconductor device 10 has the p⁻-type semiconductor regions 70, the channel regions, which are formed during the ON state, have a large length L1. That is, a channel length L1 including not only the thickness of the body region 50 under the emitter regions 60 but also the thickness of the semiconductor regions 70 can be achieved. Thus, the sum of the length L1 of the channel regions and the depth L3 of the emitter region is large, and the capacitance Cge is large. On the other hand, the trench gate electrodes 13 protrude downward from the p⁻-type semiconductor regions 70, and the length L2 of the parts of the trench gate electrodes 13 directly facing the drift region 20 is small. Therefore, the capacitance Cgc of the semiconductor device 10 is small. In the semiconductor device 10, the n⁺-type emitter regions 60 and the p⁻-type body region 50 are connected to an emitter electrode, and the p⁺-type collector region 40 is connected to a collector electrode. The emitter electrode is grounded, and on-off control of the gate voltage applied to the trench gate electrodes 13 is performed with a positive voltage of approximately a few hundred to 1000 V applied to the collector electrode.

When a gate-on voltage is applied to the trench gate electrodes 13, the p⁻-type body region 50 and the p⁻-type semiconductor regions 70 facing the trench gate electrodes 13 are inverted to n-type and channel regions are formed. Then, electrons emitted from the n⁺-type emitter regions 60 move toward the drift region 20 through the formed channels. Also, positive holes (or simply referred to as holes) move from the p⁺-type collector region 40 to the drift region 20 (schematically shown by plus signs in the drawing). Therefore, electrons and positive holes are injected into the drift region 20 to cause conductivity modulation, and the semiconductor device 10 is turned on. When the voltage applied to the trench gate electrodes 13 decreases to a value below the gate-on voltage, channel regions are no longer formed. Then, a depletion layer is widely formed from the p-n junctions between the body region 50 and the drift region 20 and so on, and the semiconductor device 10 is switched to the OFF state.

Referring next to FIG. 2 to FIG. 4, the characteristics of the semiconductor device 10 at turn-on when the semiconductor device 10 is switched on and at turn-off when the semiconductor device is switched off are described in comparison with those of a semiconductor device of the related art. Also, in the following, a case where an L-load is connected to the output side of the semiconductor device 10 is described.

FIG. 2 shows the changes in voltage Vge across the gate and the emitter at turn-on and at turn-off. In FIG. 2, the changes in the voltage Vge across the gate and the emitter in a semiconductor device of the related art are shown by solid lines, and the changes in the voltage Vge across the gate and the emitter in the semiconductor device 10 are shown by broken lines. First, the semiconductor device of the related art shown by solid lines in FIG. 2 is described. At time t0, a gate-on voltage is applied to the gate. The voltage Vge increases proportionally with time from time t0 to time t1. From time t1 to time t2, the capacitance Cgc between the gate and the collector is charged, and the voltage Vge is kept at a substantially constant value. This period is referred to as “mirror region.” The charge of the capacitance Cgc is completed at time t2, and the voltage Vge increases proportionally with time again from time t2 to time t3. At time t3, the voltage Vge reaches the steady-state value Vges of the ON state, and the semiconductor device 10 is completely switched on. The voltage to the gate is turned off at time t4, and the voltage Vge decreases proportionally with time from time t4 to time t5. Then, from time t5 to time t6, the electric charge accumulated in the capacitance Cgc is discharged and the voltage Vge is kept at a substantially constant value. The discharge of the capacitance Cgc is completed at time t6, and the voltage Vge decreases proportionally with time again from time t6 to time t7. At time t7, the voltage Vge reaches 0, and the semiconductor device 10 is completely switched off.

The semiconductor device 10 of this embodiment shown by broken lines in FIG. 2 is next described. The semiconductor device 10 has semiconductor regions 70 and thus the capacitance Cgc is small. Therefore, the mirror regions (from time t1′ to time t2′ and from time t5′ to time t6′) when the capacitance Cgc is charged or discharged are short, and the gradient (d(Vge)/dt) of the slope is gentle during the periods when the voltage increases and decreases in proportion to time.

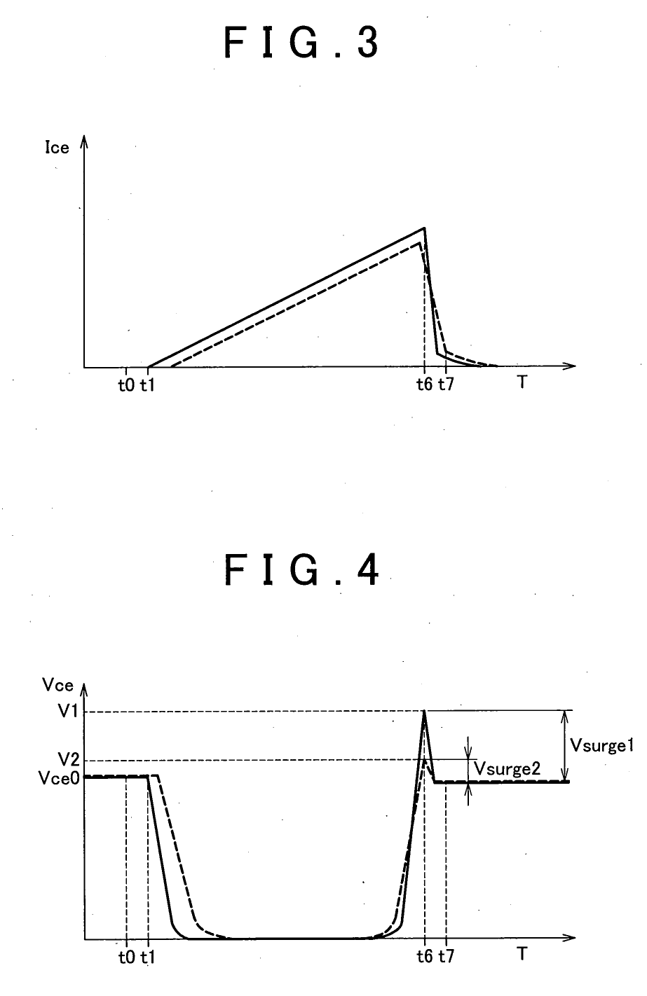

FIG. 3 shows the changes in current Ice, which flows between the collector and the emitter at turn-on and at turn-off. In FIG. 3, the changes in the current Ice in the semiconductor device of the related art are shown by solid lines. The current Ice starts to flow a short time after a gate-on voltage is applied to the gate at time t0. An L-load is connected to the output side of the semiconductor device 10, and the current Ice increases with the lapse of time. Shortly after the voltage to the gate is turned off at time t4 (see also FIG. 2), the current Ice suddenly decreases and stops flowing. In FIG. 3, the changes in the current Ice in the semiconductor device 10 of this embodiment are shown by the broken lines. Because the semiconductor device 10 has the semiconductor regions 70, the capacitance Cgc is small and the capacitance Cge is large. The response time from when the voltage to the gate is turned off to when the current Ice reaches 0, which is proportional to the product of the capacitance Cge and the value of the gate resistance (not shown) connected to the gate, is longer because the capacitance Cge is larger. Therefore, the rate of decrease of the current Ice at turn-off (dIce/dt) is lower.

FIG. 4 shows the changes in voltage Vce across the collector and the emitter at turn-on and at turn-off. In FIG. 4, the changes in the voltage Vce in the semiconductor device of the related art are shown by solid lines. The voltage Vce in the semiconductor device in OFF state is defined as Vce₀ (V). When the current Ice starts flowing between the collector and the emitter (see also FIG. 3), the voltage Vce suddenly decreases to 0. A short time after the voltage to the gate is turned off at time t4 (see also FIG. 2), the voltage Vce suddenly increases to a value higher than Vce₀ (V) in the OFF state and reaches a peak value around time t6. After that, the voltage Vce returns to Vce₀ (V). The part exceeding the Vce₀ (V) is the surge voltage, which is generated when the semiconductor device is turned off. FIG. 4 indicates that the peak value of the surge voltage Vsurge1 in the semiconductor device of the related art is V1 (V). How far the peak value of the surge voltage reaches is associated with the rate of change (d(Ice)/dt) in the current Ice, which flows between the collector and the emitter at turn-off, as shown in FIG. 3. As the rate of change in the current Ice (d(Ice)/dt) increases, the peak value of the surge voltage will be greater. In FIG. 4, the changes in the voltage Vce in the semiconductor device 10 of this embodiment are shown by broken lines. Because the semiconductor device 10 has the p⁺-type semiconductor regions 70, the capacitance Cge is large and the capacitance Cgc is small. Thus, the rate of decrease of the current Ice (dIce/dt) at turn-off is low. Therefore, the peak value of the surge voltage that is generated at turn-off is suppressed. FIG. 4 indicates that the peak value of the surge voltage Vsurge2 in the semiconductor device 10 is V2 (V), which is smaller than V1 (V).

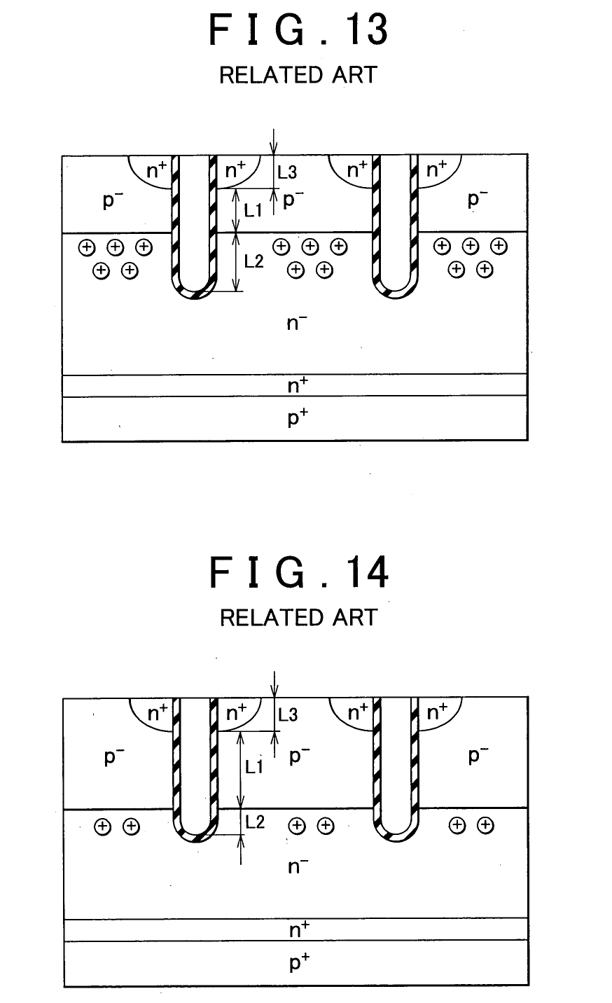

In the semiconductor device 10 of this embodiment, p⁻-type semiconductor regions (which may be regarded as fourth semiconductor regions) are added only in the vicinity of the side faces of the trench gate electrodes 13 instead of uniformly increasing the depth of the body region 50 between the paired trench gate electrodes 13 (improvement from FIG. 13 to FIG. 14). Most of the regions between the paired trench gate electrodes 13 remain to be the drift region 20. Therefore, the volume of the drift region 20 is not significantly decreased, and many holes can be accumulated in the drift region 20. As a result, the on-voltage Von can be suppressed.

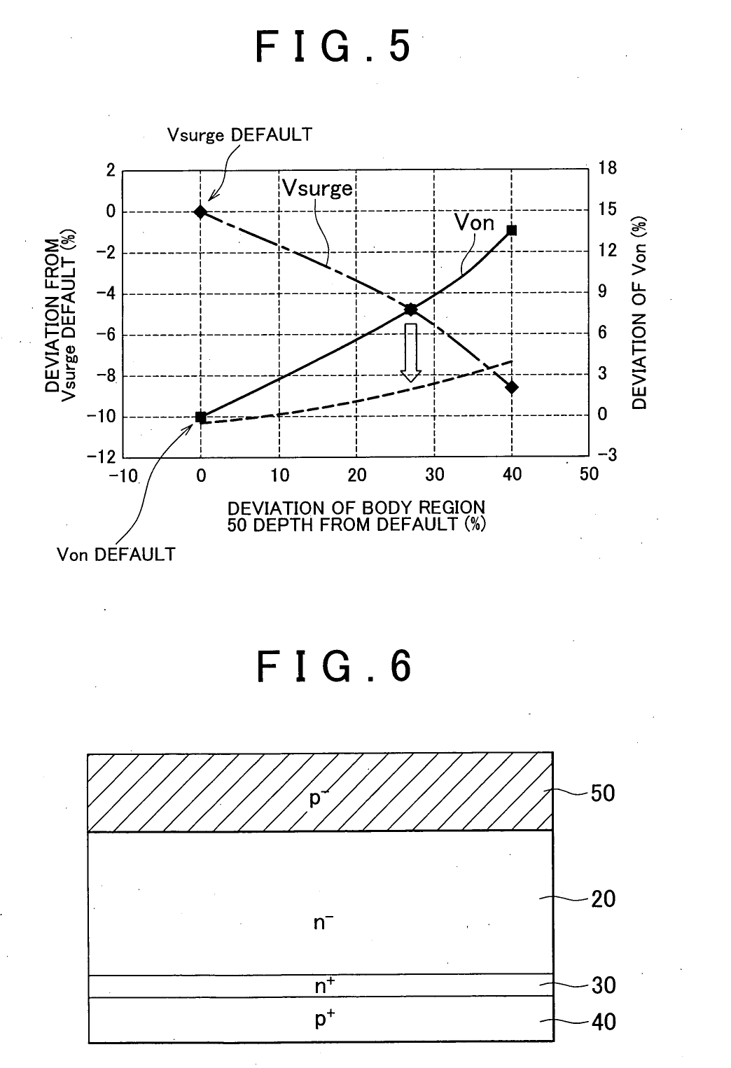

FIG. 5 shows the relation between the depth of the body region 50, and the peak value Vsurge of the surge voltage, and the on-voltage Von. The horizontal axis represents the deviation (%) of the depth of the body region 50 from a reference value (default value). The dot-and-dash line curve corresponds to the left vertical axis and represents the deviation (%) of the peak value Vsurge of the surge voltage from a default value (at 0%). The default value of the peak value Vsurge of the surge voltage means a value obtained when the depth of the body region 50 is a default value. The solid line curve corresponds to the right vertical axis, and represents the deviation (%) of the on-voltage Von from a default value (at 0%) in the semiconductor device of the related art. The default value of the on-voltage Von is the value obtained when the depth of the body region is a default value.

The broken line curve corresponds to the right vertical axis, and represents the deviation (%) of the on-voltage Von from a default value (at 0%) in the semiconductor device 10 of this embodiment. The depth of the body region is the depth to the bottoms of the p⁻-type semiconductor regions 70. In the semiconductor device 10, the semiconductor regions 70 are locally formed at the trenches instead of uniformly increasing the depth of the body region 50 (see FIG. 14). The capacitance Cge and the capacitance Cgc are affected by the semiconductor regions 70 locally formed at the trenches, but are unlikely to be affected by whether or not the p⁻-type semiconductor regions 70 adjacent to the trench gate electrodes are widely spread in the horizontal direction. The dot-and-dash line curve holds true for the semiconductor device 10. However, the on-voltage Von is affected by the volume of the drift region. In the semiconductor device 10, because the semiconductor regions 70 are locally formed at the trenches, even when the depth of the semiconductor regions 70 is increased, the volume of the drift region does not significantly change. As a result, in the semiconductor device 10 of this embodiment, the broken line curve, not the solid line curve, can be achieved. It is indicated that even when the depth of the semiconductor regions 70 is increased, the rate of increase in the on-voltage Von is low. It is confirmed that when the semiconductor device 10 is used, the peak value of the surge voltage can be effectively decreased without causing a rise in the on-voltage Von.

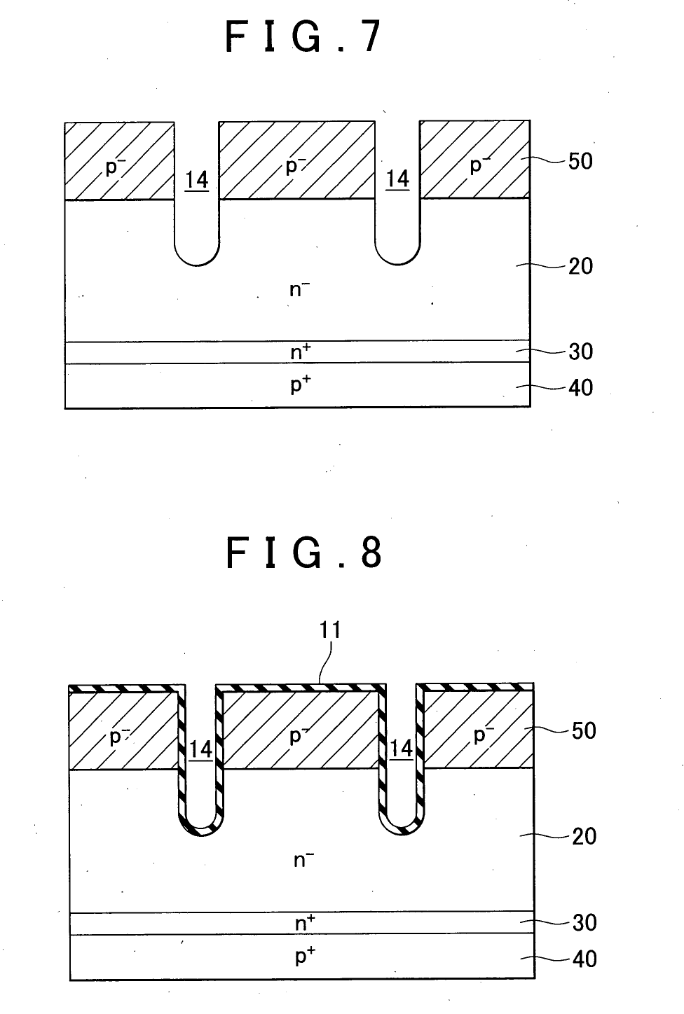

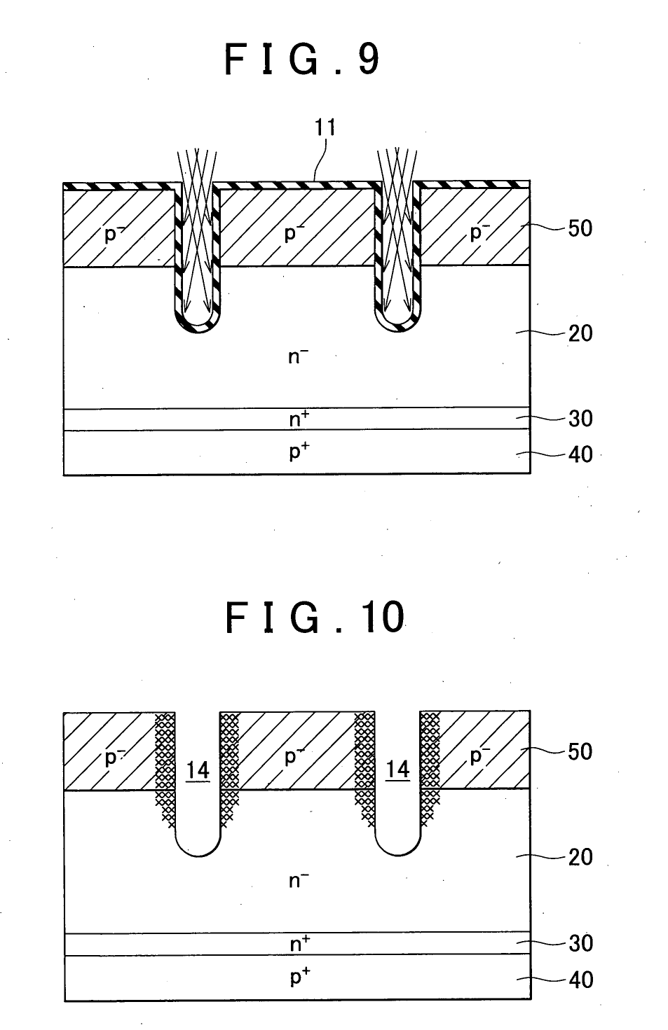

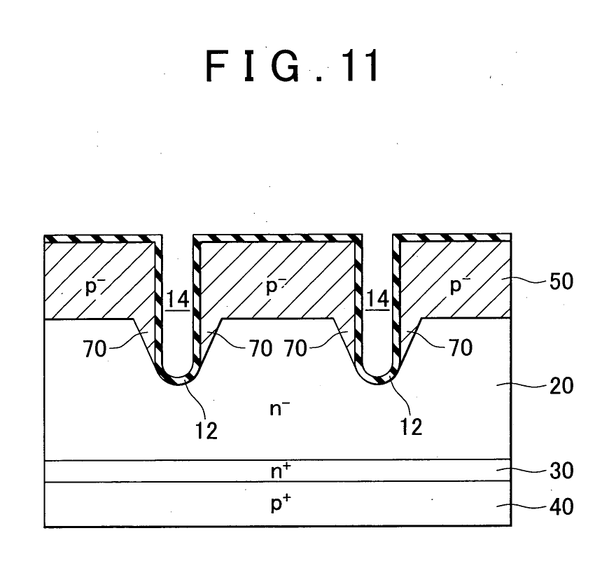

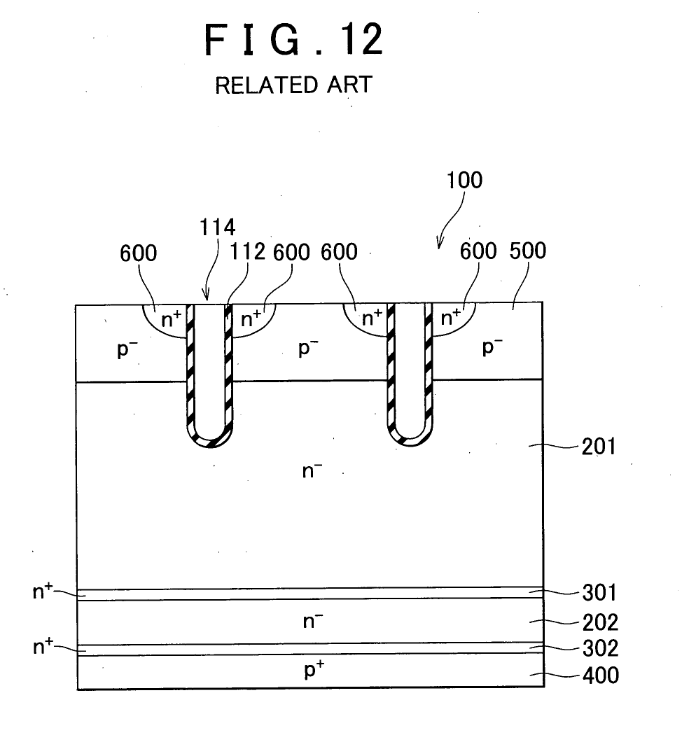

Referring next to FIG. 6 to FIG. 11, a part of the production process of the semiconductor device 10 is described. First, as shown in FIG. 6, impurity ions are doped from the bottom surface of a drift region 20 formed of an n⁻-type Si substrate, and heat treatment is performed to form an n⁺-type buffer region 30 and a p⁺-type collector region 40. Alternatively, an Si substrate for a punch through type IGBT having a layered structure of a p⁺-type collector region 40, an n⁺-type buffer region 30, and an n⁻-type drift region 20 may be used. Next, a p⁻-type body region 50 is formed on the drift region 20 by epitaxial growth. Then, as shown in FIG. 7, trenches 14 extending from the top surface of the body region 50 through the body region 50 into the drift region 20 are formed by dry etching. Then, as shown in FIG. 8, a sacrificial oxide film 11 covering the top surface of the body region 50 and the wall surfaces of the trenches 14 are formed by thermal oxidation. Then, as shown in FIG. 9, boron as p-type impurity is implanted from the top surface side of the body region 50. At this time, the boron is implanted obliquely so that the boron can hit the side faces of the trenches 14. Boron is thereby implanted into the side walls of the trenches 14 as indicated by the x-marks in FIG. 10. The amount of boron implanted is generally constant in the regions close to the tops of the trenches but gradually decreases toward the bottoms in the regions below the prescribed depth. In this embodiment, an implanting condition under which the amount of boron implanted is generally constant in the side faces in the body region 50 and gradually decrease toward the bottoms in the drift region 20 is adopted. Then, the sacrificial oxide film 11 is removed to remove the damage caused by the implantation of the impurity. Then, as shown in FIG. 11, the semiconductor substrate is subjected to heat treatment at approximately 900° C. to 1000° C. A thermal oxidation film as a gate insulator 12 is thereby formed on the wall surfaces of the trenches 14 and, at the same time, the implanted boron is activated. As a result, p⁻-type semiconductor regions 70 are formed. The p⁻-type semiconductor regions 70 are integrated with the body region 50. After that, the trenches 14 are filled with a conductive material such as polysilicon to form trench gate electrodes 13. Then, the gate insulator 12 formed on the top surface of the semiconductor layer is removed. Then, phosphorus as an n-type impurity is implanted in regions adjacent to the trench gate electrodes 14 in the top surface of the body region 50. Then, heat treatment is performed to activate the impurity to form emitter regions 60, 60 (see also FIG. 1). After that, an emitter electrode, a collector region 40 and so on are formed as in an IGBT of the related art, although not shown.

In this embodiment, when the p⁻-type semiconductor regions 70 are formed, a p-type impurity is implanted obliquely toward the side faces of the trenches 14. Therefore, the p-type implanted is injected into the side faces of the trenches 14 such that the content of the p-type impurity is lower in the regions on the bottom side and gradually

1. A semiconductor device comprising:
a third semiconductor region of a first conductivity type;
a second semiconductor region of a second conductivity type provided on the third semiconductor region;
a first semiconductor region of the first conductivity type formed in a top surface of the second semiconductor region and separated from the third semiconductor region by the second semiconductor region;
a trench extending from a top surface of the first semiconductor region through the second semiconductor region into the third semiconductor region and having a pair of opposing side faces;
an insulating layer covering wall surfaces of the trench;
a trench gate electrode surrounded by the insulating layer and disposed in the trench; and
a fourth semiconductor regions of the second conductivity type formed in contact with the side faces of the trench protruding into the third semiconductor region,
wherein:
the trench gate electrode protrudes downward from the fourth semiconductor region;
the fourth semiconductor region has a triangular shaped cross-section on both sides of the trench; and
the width of the fourth semiconductor region from the side faces of the trench increases from the bottom of the trench to the second semiconductor region.

2. (canceled)

3. The semiconductor device according to claim 1, further comprising a fifth semiconductor region of the second conductivity type on a side of a bottom surface of the third semiconductor region.

4. The semiconductor device according to claim 3, further comprising a sixth semiconductor region of the first conductivity type interposed between the third semiconductor region and the fifth semiconductor region.

5. A method of producing a semiconductor device, comprising:
forming a second semiconductor region of a second conductivity type on a third semiconductor region of a first conductivity type;
forming a first semiconductor region of the first conductivity type in a part of a top surface of the second semiconductor region;
forming a trench that extends from a top surface of the first semiconductor region through the second semiconductor region into the third semiconductor region and having a pair of opposing side faces;
forming a sacrificial oxide film covering the top surface of the second semiconductor region and wall surfaces of the trench;
implanting an impurity of the second conductivity type toward the side faces of the trench from the top surface side of the second semiconductor region to form an impurity implanted region of the second conductivity type in at least the side faces of the trench extending into the third semiconductor region;
removing the sacrificial oxide film; and
heat treating the semiconductor device to form a thermal oxidation film on wall surfaces of the trench, whereby the impurity in the impurity implanted region is activated to form a fourth semiconductor region of the second conductivity type,
wherein
the fourth semiconductor region has a triangular shaped cross-section on both sides of the trench;
the width of the fourth semiconductor region from the side faces of the trench increases from the bottom of the trench to the second semiconductor region; and
the trench protrudes downward from the fourth semiconductor region.

6. (canceled)
